(19) United States
(12) Patent Application Publication
(10) Pub. No.: US 2012/0018732 A1
(43) Pub. Date: Jan. 26, 2012

(54) INSIDE REFORMING SUBSTRATE FOR EPITAXIAL GROWTH; CRYSTAL FILM FORMING ELEMENT, DEVICE, AND BULK SUBSTRATE PRODUCED USING THE SAME; AND METHOD FOR PRODUCING THE SAME

(75) Inventors: Hideo Aida, Tokyo (JP); Natsuko Aota, Tokyo (JP); Hitoshi Hoshino, Tokyo (JP)

(73) Assignees: DISCO CORPORATION, Tokyo (JP); NAMIKI SEIMITSU HOUSEKI KABUSHIKI KAISHA, Tokyo (JP)

(21) Appl. No.: 13/144,920

(22) PCT Filed: Dec. 4, 2009
(86) PCT No.: PCT/JP2009/006633

§ 371 Date: Sep. 30, 2011

(30) Foreign Application Priority Data
Jan. 15, 2009 (JP) 2009-006293

(51) Int. Cl. H01L 29/06; H01L 21/20; H01L 21/26

(52) U.S. Cl. 257/75; 438/795; 438/478; 257/E29.005; 257/E21.328; 257/E21.09

(57) ABSTRACT

Sapphire substrates are used chiefly for epitaxial growth of nitride semiconductor layers, to provide a sapphire substrate of which the shape and/or amount of warping can be controlled efficiently and precisely and of which substrate warping that occurs during layer formation can be suppressed and substrate warping behavior can be minimized, to provide nitride semiconductor layer growth bodies, nitride semiconductor devices, and nitride semiconductor bulk substrates using such substrates, and to provide a method of manufacturing these products. Reformed domain patterns are formed within a sapphire substrate and the warp shape and/or amount of warping of the sapphire substrate are controlled by means of multiphoton absorption by condensing and scanning a pulsed laser through a polished surface of the sapphire substrate. When nitride semiconductor layers are formed using sapphire substrates obtained by means of this invention, substrate warping during layer formation is suppressed and substrate warping behavior is minimized so that layer quality and uniformity are improved and the quality and yield of nitride semiconductor devices is increased.

### BACKGROUND

This invention concerns internally reformed substrates for epitaxial growth, monocrystalline growth body, device, and bulk substrate fabricated using them, and method of manufacture for these.

Because of their broad bandgap and their capability for emission of blue light, nitride semiconductors represented by gallium nitride are widely used for light-emitting diodes (LED) and semiconductor lasers (LD). In recent years there have been numerous efforts to improve light-emission efficiency and increase luminance.

The general structure of nitride light-emitting devices has been a double heterostructure in which a buffer layer of GaN, an n-type contact layer of n-GaN, an n-type clad layer of n-AlGaN, an active layer of n-InGaN, and a p-type contact layer of p-AlGaN are stacked in that order on a sapphire substrate. Active layer structures include the single quantum well (SQW) structure which is one well layer of InₓGa1₋ₓN (where 0≦x≦1) and the multi quantum well (MQW) structure which has a well layer of InₓGa1₋ₓN (where 0≦x≦1) and a barrier layer of In_{y}Ga1_{-y}N (where 0≦x≦1 and y<x). (Patent Document 1)

It is known that when the gallium nitride layer is formed on the sapphire substrate by epitaxial growth, warping of the sapphire substrate occurs after layer formation because of the difference of indices of thermal expansion and the difference in lattice constant between the gallium nitride and the sapphire.

Non-patent Document 1 discusses how the thermal stress that develops through epitaxial growth of an AN buffer layer and a GaN layer on a sapphire substrate can be eased, depending on the thickness of the GaN layer. It is clear from this Non-patent Document 1 that warping of the substrate increases as the thickness of the grown layer increases and stress is eased by the occurrence of the resultant interface defects, microcracks, dislocations, and macrocracks.

Moreover, FIG. 4 of Non-patent Document 2 discloses an analytical method for in-situ observation of substrate warping that arises in the process of epitaxial growth of a GaN LED structure on a sapphire substrate. This indicates that the curvature of the sapphire substrate in a series of growth processes varies greatly with variations in the material of the growth layer, the growth temperature, and thickness of the layer.

Thus it was made clear that by means of a growth process such that the curvature of the sapphire substrate would be nearly 0 during growth of an InGaN layer that is the active layer, the light emission wavelength at the surface of the substrate can be made uniform.

As above, it is known that warping of a sapphire substrate varies greatly in a series of layer growth processes and that it affects the quality of nitride semiconductor layers and uniformity of the emitted wavelength.

In fact it is possible, using the difference in the index of thermal expansion from that of the substrate, to set the shape and amount of sapphire substrate warping so that there is nearly 0 substrate curvature in the InGaN active layer. Given that background, various polishing techniques have been considered in order to control the shape and amount of sapphire substrate warping (Patent Document 2, for example).

When partitioning light-emitting elements that are nitride semiconductors stacked on a sapphire substrate, on the other hand, there is a known technology of condensing a pulsed laser within a sapphire substrate having a thickness of about 89 to 90 μm to form changed domains corresponding to the lines planned for partition of the light-emitting elements (Patent Document 3). The invention of Patent Document 3 is a method of processing sapphire substrates by illuminating a sapphire substrate with a laser beam to suppress the loss of luminance of the light-emitting elements when partitioning into individual light-emitting elements; its purpose is the partitioning of light-emitting elements.

### PATENT DOCUMENTS

[Patent Document 1] Patent Report 3250438
[Patent Document 2] Pre-grant Patent Report 2006-347776
[Patent Document 3] Pre-grant Patent Report 2008-6492

### NON-PATENT DOCUMENTS

[Non-Patent Document 1] Jpn. J. Appl. Phys., Vol. 32 (1993), pp. 1528-1533
[Non-Patent Document 2] J. Cryst. Growth, Vol. 272, Issues 1-4 (2004), pp. 94-99

### SUMMARY

As stated above, the warping of sapphire substrates through a series of growth processes to yield a gallium nitride light-emitting diode structure varies greatly, and so there is the problem of poor quality of the nitride semiconductor layer, poor uniformity of the emitted wavelength, and poor yield of light-emitting diodes.

The conventional method for dealing with this problem is that of setting the shape and amount of sapphire substrate warping so that the curvature of the substrate in the stage of InGaN active layer growth is nearly 0. In other words, it is a method of treating the sapphire substrate in advance to counteract the amount of warping that will occur in the stage of InGaN active layer growth. Although this method does hold down the scattering of the emitted wavelengths to some extent, there remains the unresolved problem of substrate warping that occurs during processes to grow layers other than the InGaN active layer.

Sapphire substrates warp greatly during the stage of n-GaN layer growth and as the substrates cool down after completion of layer formation, and so there are problems such as reduced layer quality and reduced uniformity of layer quality, as well as the difficulty of uniformity in the substrate back grinding process. Because these problems have a great effect on the yield of devices such as light-emitting diodes, it is necessary to suppress substrate warping and change of the amount of warping through all growth processes and to minimize substrate warping behavior itself. However, sapphire substrates of this sort have not existed heretofore.

There is the further problem that as sapphire substrates increase in diameter, it becomes more difficult to control the precise shape and amount of warping through the polishing process. It is known that in a sapphire substrate that has undergone a polishing process substrate warping normally occurs as a result of residual machining discrepancies and differences of surface coarseness between the top and bottom surfaces. In a substrate with one polished surface, for example, the cause of warping is primarily the difference of surface coarseness between the top and bottom surfaces, and in a substrate with two polished surfaces the cause of warping is slight variation in the surface coarseness of each face of the substrate in addition to slight differences of surface coarseness between the top and bottom surfaces.

There are technical problems, particularly in the case of large-diameter substrates, in making surface coarseness uniform between the substrate surfaces, and so there is the problem in the technical realm that the desired shape and amount of warping cannot be controlled precisely by the polishing process alone.

There is the further problem that when, in order to obtain a nitride semiconductor bulk substrate, one attempts epitaxial growth to such a thickness that the thick layer of nitride semiconductor can exist independently, there will be great warping of the sapphire substrate because of the different indices of thermal expansion of the sapphire and the nitride semiconductor and the amount of this warping will increase with the thickness of the layer formed. As a result, cracking may occur during and after layer growth, making it essentially impossible to obtain nitride semiconductor bulk substrates that can exist independently.

Means to resolve these problems have been proposed, including the epitaxial lateral over growth (ELOG) method, the dislocation elimination of inverted-pyramidal pits (DEEP) method, and the void-assisted separation (VAS) method, but they all have the defect that processes becomes complicated.

In consideration of these problems, the purpose of this invention is, in the field of sapphire substrates used chiefly for epitaxial growth of nitride semiconductor layers, to provide a sapphire substrate of which the shape and/or amount of warping can be controlled efficiently and precisely and of which substrate warping that occurs during layer formation can be suppressed and substrate warping behavior can be minimized, to provide nitride semiconductor layer growth bodies, nitride semiconductor devices, and nitride semiconductor bulk substrates using such substrates, and to provide a method of manufacturing these products.

The present inventors discovered that by using a pulsed laser to form a reformed domain pattern within a sapphire substrate for epitaxial growth of a nitride semiconductor layer it is possible to control stresses in the sapphire substrate and to control efficiently the shape and/or amount of substrate warping.

Further, it was discovered that when the sapphire substrates obtained from this invention are used to form nitride semiconductor layers, the stresses generated by layer growth are counteracted by the stresses in the sapphire substrate in which the reformed domain pattern has been formed and it becomes possible to suppress substrate warping in the layer growth process and to minimize substrate warping behavior. With this discovery the invention was completed.

That is, among sapphire substrates used for formation of a semiconductor layer formed by epitaxial growth, the internally reformed sapphire substrate for epitaxial growth of a semiconductor layer of this invention is one in which a reformed domain pattern is formed within the sapphire substrate by means of multiphoton absorption using a pulsed laser condensed and scanned through a polished surface of the sapphire substrate.

Moreover, the internally reformed sapphire substrate for epitaxial growth of a semiconductor layer of this invention is fabricated by forming a reformed domain pattern within the sapphire substrate by means of multiphoton absorption using a pulsed laser condensed and scanned through a polished surface of the sapphire substrate.

Moreover, the internally reformed sapphire substrate for epitaxial growth of a semiconductor layer of this invention is one in which, in addition to the inventions described above, the plane shape of at least one type of reformed domain pattern is any of a striped shape, a lattice shape, a distribution of multiple polygons, a concentric circular shape, a spiral shape, or broken lines or dots that are symmetrical with respect to a vertical line through the center point of the sapphire substrate.

Moreover, the internally reformed sapphire substrate for epitaxial growth of a semiconductor layer of this invention is one in which the position of formation of at least one type of reformed domain pattern is between 3% and 95% of the thickness of the substrate from the growth surface of the internally formed sapphire substrate and the pitch between lines making up the reformed domain pattern is at least 50 μm and no more than 2000 μm.

Moreover, the internally reformed sapphire substrate for epitaxial growth of a semiconductor layer of this invention is one in which the plane shape of at least one type of reformed domain pattern the plane shape of at least one type of reformed domain pattern is any of broken lines or dots that are symmetrical with respect to a vertical line through the center point of the internally formed sapphire substrate or a lattice pattern and the reformed domain pattern is positioned between 3% and 50% of the thickness of the substrate from the growth surface of the sapphire substrate and the pitch between lines making up the reformed domain pattern is at least 50 μm and no more than 2000 μm.

Moreover, the nitride semiconductor layer growth body of this invention is one in which at least one nitride semiconductor layer is formed on the growth surface of an internally reformed sapphire substrate for epitaxial growth of nitride semiconductor layers.

Moreover, the nitride semiconductor device of this invention is one fabricated using the nitride semiconductor growth layer body of this invention.

Moreover, the bulk nitride semiconductor substrate of this invention is one fabricated using a thick nitride semiconductor layer of this invention.

Moreover, the internally reformed sapphire substrate for epitaxial growth of a nitride semiconductor layer of this invention is one fabricated using a sapphire substrate for formation of a reformed domain pattern which prior to formation of the reformed domain pattern has a semiconductor layer growth surface that is concave and the curvature of the concave surface is greater than 0 km⁻¹ and not greater than 160 km⁻¹.

Moreover, the internally reformed sapphire substrate for epitaxial growth of a nitride semiconductor layer of this invention is one fabricated using a sapphire substrate for formation of a reformed domain pattern which prior to formation of the reformed domain pattern has a semiconductor layer growth surface that is concave and the curvature of the concave surface is greater than 40 km⁻¹ and not greater than 150 km⁻¹.

Moreover, the internally reformed sapphire substrate for epitaxial growth of a nitride semiconductor layer of this invention is one fabricated using a sapphire substrate for formation of a reformed domain pattern which prior to formation of the reformed domain pattern has a semiconductor layer growth surface that is concave and the curvature of the concave surface is greater than 85 km⁻¹ and not greater than 150 km⁻¹.

Moreover, the sapphire substrate for reformed domain formation of this invention is one in which the diameter of the sapphire substrate prior to reformed domain formation is at least 50 mm and no more than 300 mm and its thickness is at least 0.05 mm and no more than 5.0 mm.

The internally reformed sapphire substrate of this invention can be applied in epitaxial growth of semiconductor layers of various types, including nitride semiconductor layers. Moreover, it [the invention] can be applied to any monocrystalline substrate other than sapphire in which pattern formation of reformed domains can be done internally using a pulsed laser. In particular, it can be used with any monocrystalline substrate used for epitaxial growth to resolve the problem of substrate warping that occurs in homoepitaxial growth, including unified and mixed-crystal systems, not just in heteroepitaxial growth. For that reason, it can improve the quality and yield of a variety of devices and bulk substrates.

This invention has the effects described below.

In accordance with the claimed invention, it is possible to provide, among monocrystalline substrates used for formation of monocrystalline layers by means of epitaxial growth, monocrystalline substrates with efficiently and precisely controlled substrate warp shape and/or amount. This invention is particularly effective in the case of large diameter substrates where control by the polishing process alone is technically difficult. There is the further effect that it is possible to provide monocrystalline substrates in which warping that occurs in the epitaxial growth process can be suppressed and substrate warping behavior can be minimized.

In accordance with the claimed invention, the effects of the above noted invention are available for monocrystalline substrates such as sapphire, nitride semiconductor, Si, GaAs, quartz crystal, or SiC. in which a reformed domain pattern can be formed within the substrate using a pulsed laser.

In accordance with the claimed invention, it is possible to counteract the stresses that occur during layer formation with stresses in the monocrystalline substrate in which a reformed domain pattern has been formed, and so it is possible to suppress warping that occurs during layer formation and minimize substrate warping behavior.

This effect makes it possible to check dislocations during crystal formation and the lack of uniformity of layer thickness, and possible to obtain crystal layer formation bodies with improved layer quality and uniformity. It is possible to constitute various devices using the crystal layer formation bodies of this invention. Moreover, the crystal layer formation bodies of this invention can be used as bed substrates when using epitaxial growth to form thick layers of a thickness to exist independently.

In accordance with the claimed invention, it is possible to constitute various devices using the crystal layer formation bodies with improved layer quality and uniformity, and so it is possible to provide various devices having improved quality and yields.

In accordance with the claimed invention, it is possible to suppress substrate warping that occurs during and after layer growth, and so it is possible to grow thick layers without using complicated processes and without causing cracking. It is therefore possible to provide various bulk substrates that comprise thick crystal growth layers having a thickness to exist independently.

In accordance with the claimed invention, it is possible to provide, among sapphire substrates used for epitaxial growth of semiconductor layers, sapphire substrates in which the shape and/or amount of substrate warping is efficiently and precisely controlled. Further, because reformed domain patterns are formed internally in the sapphire substrates of this invention, rewashing of the substrates is unnecessary. This invention is particularly effective for large diameter substrates for which control by the polishing process alone is technically difficult.

Moreover, using the sapphire substrate of this invention has the effect of making it possible to suppress substrate warping that occurs in the process of epitaxial growth of semiconductor layers and to minimize substrate warping behavior. Further, because the pattern is not on the surface of the sapphire substrate, there is no need for a major change of growth conditions and it is possible to conduct layer growth under the same conditions as conventional sapphire substrates.

In accordance with the claimed invention, the stresses generated by formation of a semiconductor layer can be counteracted by stresses in the sapphire substrate in which a reformed domain pattern is formed, and so it is possible to suppress substrate warping that occurs in the process of epitaxial growth of semiconductor layers and to minimize substrate warping behavior.

As a result it is possible to check dislocations during crystal formation and the lack of uniformity of layer thickness, and possible to obtain crystal layer formation bodies with improved layer quality and uniformity. It is possible to constitute various devices using the crystal layer formation bodies of this invention. Moreover, the crystal layer formation bodies of this invention can be used as bed substrates when using epitaxial growth to form thick layers of a thickness to exist independently.

In accordance with the claimed invention, it is possible to constitute various devices using the crystal layer formation bodies with improved layer quality and uniformity, and so it is possible to provide various semiconductor devices with improved quality and yield.

In accordance with the claimed invention, it is possible to suppress substrate warping that occurs in the process of epitaxial growth of semiconductor layers, and so it is possible to grow thick layers without using complicated processes and without causing cracking. It is therefore possible to provide various bulk substrates that comprises thick crystal growth layers having a thickness to exist independently.

In accordance with the claimed invention, it is possible to provide, among sapphire substrates used for epitaxial growth of nitride semiconductor layers, sapphire substrates in which the shape and/or amount of substrate warping is efficiently and precisely controlled. Further, because reformed domain patterns are formed internally in the sapphire substrates of this invention, rewashing of the substrates is unnecessary. This invention is particularly effective for large diameter substrates for which control by the polishing process alone is technically difficult.

Moreover, using the sapphire substrate of this invention has the effect of making it possible to suppress substrate warping that occurs in the process of epitaxial growth of semiconductor layers and to minimize substrate warping behavior. Further, because the pattern is not on the surface of the sapphire substrate, there is no need for a major change of growth conditions and it is possible to conduct layer growth under the same conditions as conventional sapphire substrates.

In accordance with the claimed invention, the effect that it is possible to provide a sapphire substrate in which chiefly the shape of substrate warping is uniform.

In accordance with the claimed invention, the effect that it is possible to provide a sapphire substrate in which chiefly the amount of substrate warping is uniform.

In accordance with the claimed invention, the effect that it is possible to provide a sapphire substrate with which it is possible to suppress substrate warping that occurs in the process of epitaxial growth of semiconductor layers and to minimize substrate warping behavior.

In accordance with the claimed invention, the stresses generated by formation of a semiconductor layer can be counteracted by stresses in the sapphire substrate in which a reformed domain pattern is formed, and so it is possible to suppress substrate warping that occurs in the process of epitaxial growth of semiconductor layers and to minimize substrate warping behavior.

This effect makes it possible to check dislocations in the nitride semiconductor layer and the lack of uniformity of layer thickness, and possible to obtain nitride semiconductor layer formation bodies with improved layer quality and uniformity. It is possible to constitute various nitride semiconductor devices using the nitride semiconductor layer formation bodies of this invention. Moreover, the nitride semiconductor layer formation bodies of this invention can be used as bed substrates when using epitaxial growth to form thick layers of a thickness to exist independently.

In accordance with the claimed invention, it is possible to constitute various devices using the nitride semiconductor layer formation bodies with improved layer quality and uniformity, and so it is possible to provide various nitride semiconductor devices with improved quality and yield.

In accordance with the claimed invention, it is possible to provide, in particular, photo-emitter elements, electron devices, or photo-receptor elements as nitride semiconductor devices.

In accordance with the claimed invention, it is possible to suppress substrate warping that occurs during and after layer growth of nitride semiconductor layers, and so it is possible to grow thick nitride semiconductor layers without using complicated processes and without causing cracking. It is therefore possible to provide various nitride semiconductor bulk substrates that comprise thick nitride semiconductor layers having a thickness to exist independently.

In accordance with the claimed invention, it is possible to provide bulk nitride semiconductor substrates in which the bulk nitride semiconductor substrate comprises AlₓIn_{y}Ga_{z}N (where x+y+z=1, x≧0, y≧0, and z≧0).

In accordance with the claimed invention, it is possible to fabricate internally reformed sapphire substrates of which the shape and/or amount of warping can be controlled precisely.

In accordance with the claimed invention, the effect that it is possible to fabricate internally reformed sapphire substrates with which it is possible to suppress substrate warping that occurs in the process of epitaxial growth of nitride semiconductor layers and to minimize substrate warping behavior.

In accordance with the claimed invention, it is possible to efficiently fabricate internally reformed sapphire substrates with which it is possible to precisely control the shape and/or amount of substrate warping, to suppress substrate warping that occurs in the process of epitaxial growth of nitride semiconductor layers.

In accordance with the claimed invention, it is possible to precisely control the shape and/or amount of monocrystalline substrate warping. This invention is particularly effective in the case of large diameter substrates where control by the polishing process alone is technically difficult.

In accordance with the claimed invention, the effects of the above noted invention are available for monocrystalline substrates such as sapphire, nitride semiconductor, Si, GaAs, quartz crystal, or SiC. in which a reformed domain pattern can be formed within the substrate using a pulsed laser.

In accordance with the claimed invention, it is possible to suppress substrate warping that occurs in the process of epitaxial growth of substrate semiconductor layers and to minimize substrate warping behavior, and so it is possible to check dislocations during crystal formation and the lack of uniformity of layer thickness, and possible to improve layer quality and uniformity.

In accordance with the claimed invention, it is possible to constitute various device using the crystal layer formation bodies with improved layer quality and uniformity, and so it is possible to provide various devices having improved quality and yields.

In accordance with the claimed invention, it is possible to suppress substrate warping that occurs during and after layer growth, and so it is possible to grow thick layers without using complicated processes and without causing cracking. It is therefore possible to provide various bulk substrates that comprise thick crystal growth layers having a thickness to exist independently.

In accordance with the claimed invention, it is possible to efficiently and precisely control substrate warp shape and/or amount in sapphire substrates used for epitaxial growth of nitride semiconductor layers. This invention is particularly effective for large diameter substrates for which control by the polishing process alone is technically difficult. Further, because reformed domain patterns are formed internally in the sapphire substrates of this invention, rewashing of the substrates is unnecessary.

In accordance with the claimed invention, it is possible to suppress substrate warping that occurs in the process of epitaxial growth of semiconductor layers and to minimize substrate warping behavior, and so it is possible to check dislocations during semiconductor layer formation and the lack of uniformity of layer thickness, and possible to improve layer quality and uniformity. Further, because the pattern is not on the surface of the sapphire substrate, there is no need for a major change of growth conditions and it is possible to conduct layer growth under the same conditions as conventional sapphire substrates.

In accordance with the claimed invention, it is possible to constitute various semiconductor devices with improved layer quality and uniformity, and so it is possible to manufacture various nitride semiconductor devices with improved quality and yield.

In accordance with the claimed invention, it is possible to suppress substrate warping that occurs during and after layer growth, and so it is possible to grow thick layers without using complicated processes and without causing cracking. It is therefore possible to provide various bulk substrates that comprise thick semiconductor layers having a thickness to exist independently.

In accordance with the claimed invention, it is possible to efficiently and precisely control substrate warp shape and/or amount in sapphire substrates used for epitaxial growth of nitride semiconductor layers. This invention is particularly effective for large diameter substrates for which control by the polishing process alone is technically difficult. Further, because reformed domain patterns are formed internally in the sapphire substrates of this invention, rewashing of the substrates is unnecessary.

In accordance with the claimed invention, in addition to the effects of the above noted invention it is possible to provide a sapphire substrate in which chiefly the shape of substrate warping is uniform.

In accordance with the claimed invention, in addition to the effects of the above noted invention it is possible to provide a sapphire substrate in which chiefly the amount of substrate warping is uniform.

In accordance with the claimed invention, in addition to the effects of the above noted invention it is possible to provide a sapphire substrate with which it is possible to suppress substrate warping that occurs in the process of epitaxial growth of semiconductor layers and to minimize substrate warping behavior.

In accordance with the claimed invention, it is possible to suppress substrate warping that occurs during layer formation and to minimize substrate warping behavior, and so it is possible to check dislocations in the nitride semiconductor layer and the lack of uniformity of layer thickness and to improve layer quality and uniformity. Further, because the pattern is not on the surface of the sapphire substrate, there is no need for a major change of growth conditions and it is possible to conduct layer growth under the same conditions as conventional sapphire substrates.

In accordance with the claimed invention, it is possible to constitute various devices using the nitride semiconductor layer formation bodies with improved layer quality and uniformity, and so it is possible to manufacture various nitride semiconductor devices with improved quality and yield.

In accordance with the claimed invention, it is possible to improve the quality and yield of nitride semiconductor devices, particularly photo-emitter elements, electron devices, or photo-receptor elements.

In accordance with the claimed invention, it is possible to suppress substrate warping that occurs during and after layer growth, and so it is possible to grow thick layers without using complicated processes and without causing cracking. It is therefore possible to manufacture various bulk substrates that comprise thick nitride semiconductor layers having a thickness to exist independently.

In accordance with the claimed invention, it is possible to manufacture, without cracking, thick nitride semiconductor layers that comprise, in particular, AlₓIn_{y}Ga_{z}N (where x+y+z=1, x≧0, y≧0, and z≧0).

In accordance with the claimed invention, it is possible to fabricate efficiently internally reformed sapphire substrates in which the shape and/or amount of substrate warping is precisely controlled.

In accordance with the claimed invention, in addition to the effects of the above noted invention, it is possible to efficiently manufacture internally reformed sapphire substrates in which the shape and/or amount of substrate warping is precisely controlled and with which it is possible, in the process of forming nitride semiconductor layers, to suppress substrate warping and minimize substrate warping behavior.

In accordance with the claimed invention, it is possible to efficiently manufacture internally reformed sapphire substrates in which the shape and/or amount of substrate warping is precisely controlled and with which it is possible, in the process of forming nitride semiconductor layers, to suppress substrate warping and minimize substrate warping behavior.

### BRIEF DESCRIPTION OF THE DRAWINGS

FIG. 1 A diagram showing formation of a reformed domain within a monocrystalline substrate of an embodiment of this invention.

FIG. 2 A diagram showing the pattern shape, pitch, and position of a reformed domain pattern of this embodiment.

FIG. 3 A diagram showing the process of epitaxial growth of a nitride semiconductor layer of this embodiment.

FIG. 4 A diagram showing an example of in-situ observation during the semiconductor growth process of this embodiment.

FIG. 5 A diagram showing the relationship between warp amount and curvature of a substrate of this embodiment.

FIG. 6 A diagram showing an example of in-situ observation using a sapphire substrate of this invention in this embodiment.

FIG. 7 A diagram showing formation position and pitch dependence relative to the amount of change of substrate curvature following formation of the reformed domain pattern in embodiment 2.

FIG. 8a A diagram showing the results of in-situ observation of sample 10 of embodiment 3.

FIG. 8b A diagram showing the results of in-situ observation of sample 12 of embodiment 3.

FIG. 8c A diagram showing the results of in-situ observation of sample 14 of embodiment 3.

FIG. 8d A diagram showing the results of in-situ observation of sample 16 of embodiment 3.

FIG. 8e A diagram showing the results of in-situ observation of sample 18 of embodiment 3.

FIG. 8f A diagram showing the results of in-situ observation of sample 20 of embodiment 3.

### DETAILED DESCRIPTION

The optimal embodiment of this invention is explained below.

The internally reformed substrate for epitaxial growth of this invention is fabricated by condensing and scanning a pulsed laser through the polished surface of a monocrystalline substrate into the monocrystalline substrate used for layer growth of a crystalline layer by means of epitaxial growth, thus forming a reformed domain pattern by using multiphoton absorption by the pulsed laser.

The monocrystalline substrate can be any material in which reformed domains can be formed internally using multiphoton absorption with a pulsed laser, including sapphire, nitride semiconductor, Si, GaAs, quartz crystal, or SiC.

The wavelength of the pulsed laser used should be longer than the absorption edge wavelength of the monocrystalline substrate chosen and within the transparent wavelength region. The pulse width and irradiation energy must be selected to match the properties of the substrate material.

When the monocrystalline substrate is sapphire, the pulsed laser wavelength is preferably at least 200 nm and no more than 5000 nm, the pulse width is in the picosecond or femtosecond range, preferably from 200 fs to 800 fs, and the pulse repetition rate is preferably from 50 kHz to 500 kHz. The laser power is preferably 0.05 to 0.8 W and the laser spot size is 0.5 to 4 μm; the spot size is preferably about 2 μm. The scan speed of the sample stage is preferably 100 to 1000 mm/s in consideration of mass production.

Table 1 shows typical machining conditions that can form reformed domains in Si, GaAs, and quartz crystal.

TABLE 1

| | Si | GaAs | Quartz Crystal |
|---|---|---|---|
| Wavelength (nm) | 1064 | 1064 | 1045 |
| Pulse width (sec) | 120 × 10⁻⁹ | 70 × 10⁻⁹ | 500 × 10⁻¹⁵ |
| Pulse Repetition Rate (kHz) | 100 | 15 | 100 |
| Spot Size (μm) | 1.5 | 1.5 | 1 |
| Laser Power (W) | 0.3 to 1.2 | 0.2 | 0.4 |
| Stage Scan Speed (mm/s) | 200 to 300 | 200 | 400 |

For Si, GaAs, and quartz crystal the spot size is preferably in the range from 0.5 μm to 4 μm. The stage scan speed is 50 mm/s to 1000 mm/s, or 100 mm/s to 1000 mm/s in consideration of mass production. The pulse width is preferably 50 ns to 200 ns for Si, 30 ns to 80 ns for GaAs, and 200 fs to 800 fs for quartz crystal. The irradiation energy is preferably 3 μJ to 12 μJ for Si, 8 μJ to 20 μJ for GaAs, and 3 μJ to 6 μA for quartz crystal. The pulse repetition rate is preferably 10 kHz to 500 kHz.

The size of the monocrystalline substrate is not limited; diameters from 50 mm to 300 mm can be used. Substrates with thicknesses from 0.05 mm to 5.0 mm can be used.

The monocrystalline substrate should be polished, at least on the surface used for formation of a crystalline layer formed by epitaxial growth. Warping normally occurs in monocrystalline substrates because of residual machining distortions or differences in surface coarseness from the polishing process. For example, in a substrate with one polished surface, for example the cause of warping is primarily the difference of surface coarseness between the top and bottom surfaces, and in a substrate with two polished surfaces the cause of warping is slight variation in the surface coarseness of each face of the substrate in addition to slight differences of surface coarseness between the top and bottom surfaces.

The term “epitaxial growth” includes homoepitaxial growth, both unified and mixed-crystal systems, as well as heteroepitaxial growth.

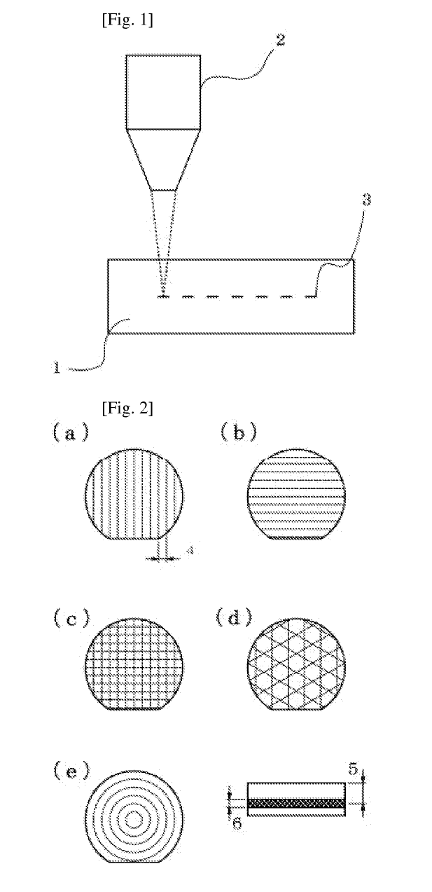

As shown in FIG. 1, when a pulsed laser 2 is condensed into monocrystalline substrate 1 through its polished surface and scanned at a constant speed with the sample stage, spot-shaped reformed domains 3 are continuously connected to form a linear reformed domain.

Viewed locally, the spot-shaped reformed domain 3 is formed only in the portion irradiated instantaneously by the pulsed laser; its size depends on the laser's spot size, the laser intensity and the pulse width. Further, the separation of the spot-shaped reformed domains formed linearly depends on the laser's pulse repetition rate and the scan speed of the stage.

Combining these linear reformed domains forms at least one type of reformed domain pattern at the desired position, in the direction of depth, in the substrate. The term “reformed domain” indicates the changed layer formed by the local occurrence of multiphoton absorption in the area irradiated by the laser.

As shown in FIG. 2, it is possible to control the stresses in the substrate as a whole and precisely control the shape and amount of substrate warping by optimizing such conditions as the pattern shape of the reformed domain pattern, the pitch 4 between lines, the formation position 5, and the reformed layer length 6.

With regard to the pattern shape, as shown in FIG. 2 the plane shape can be, for example, a striped shape with multiple lines formed perpendicular or parallel to the orientation flat of the substrate (FIGS. 2 (a) and (b)) or a lattice combining these two directions (FIG. 2 (c)). Other possible shapes are a distribution of multiple polygons (FIG. 2 (d)), concentric circles (FIG. 2 (e)), and so on.

Because the pattern shape primarily affects the symmetry of the substrate warping shape, if a warping shape that is uniform across the surface of the substrate is to be obtained, the preferable plane shape is a pattern of broken lines or dots that are symmetrical with respect to a vertical line through the center point of the substrate. Conversely, if the plane shape is striped it is possible to impose a bias to the warping shape of the substrate.

The pitch 4 between lines primarily affects the amount of change of the and amount of warping in the substrate following the reformed domain pattern formation; the smaller the pitch between lines, the larger the amount of change. Because decreasing the pitch increases the machining time, 50 μm to 2000 μm is preferable, and 100 μm to 1000 μm is better yet when mass production is taken into consideration.

The formation position 5 primarily affects the amount of change of the and amount of warping in the substrate following the reformed domain pattern formation; the closer the formation position to the surface, the greater the amount of change. To avoid affecting the growth surface of a monocrystalline substrate, the formation position of at least one type of reformed domain pattern is preferably set to at least 3% and no more than 95% of substrate thickness and better yet at least 3% and no more than 50%, measuring from the growth surface of the substrate. Multiple reformed domain patterns can be formed at formation positions that differ in the direction of the depth of the substrate.

The reformed layer length 6 depends on the laser's spot size, irradiation energy (laser power divided by the pulse repetition rate), and pulse width; it is normally formed with a depth from several microns to several tens of microns.

As stated above, internally reformed substrates with precisely controlled warping shapes and/or amounts can be obtained efficiently by forming reformed domain patterns within monocrystalline substrates and controlling the stresses in the substrates.

Further, it is possible to form at least one crystal layer by epitaxial growth on the growth surface of the internally reformed substrate yielded by this invention and to fabricate crystal growth bodies. The method of formation of the crystalline layer can be either vapor phase growth or liquid phase growth. For example, various crystal growth methods such as MBE, CVD, VPE, LPE, or sublimation can be used.

Using the internally reformed substrate of this invention it is possible to counteract the stresses that occur through layer formation with the stresses of the internally reformed substrate, and so it is possible to suppress substrate warping in the layer growth process and to minimize substrate warping behavior. It is therefore it possible to obtain crystal growth layer bodies with increased crystalline layer quality and uniformity.

Using the crystal growth layer bodies obtained through this invention it is possible to improve device quality and yield when constituting various devices.

Further, it is possible to use the crystal growth layer body of this invention as a bed substrate for epitaxial growth to form a thick crystalline layer of a thickness to exist independently. Further, it is possible to separate the thick crystalline layer from the bed substrate that is a crystal growth layer body to yield a bulk substrate.

Moreover, it is possible to obtain a bulk substrate that comprises a thick crystalline growth layer by forming a thick crystalline growth layer on the internally reformed substrate of this invention and separating it from the internally reformed substrate. When using the internally reformed substrate of this invention, it is possible to suppress substrate warping that occurs during or after layer growth, and so it is possible to form a thick layer without cracking.

The independent thick layer is preferably at least 50 μm thick. Such methods as MOCVD, HVPE or LPE can be used to form the thick layer.

By using a sapphire substrate as the monocrystalline substrate it is possible to obtain an internally reformed sapphire substrate that has the same effects as the internally reformed substrate described above, and that is suited to formation of semiconductor layers by means of epitaxial growth.

Further, it is possible to fabricate a semiconductor layer growth body by using epitaxial growth to form at least one semiconductor layer on the growth surface of the internally reformed sapphire substrate of this invention. Using the semiconductor layer growth bodies obtained through this invention it is possible to obtain semiconductor devices and semiconductor bulk substrates.

Particularly when the semiconductor layer is a nitride semiconductor layer, it is possible to use sapphire substrates diameters from 50 mm to 300 mm as substrates for the growth of nitride semiconductors. Because the effects of this invention are greater in substrates of larger diameter, the invention is particularly useful for large diameter substrates of 75 mm or more and preferably of 150 mm or more. Despite that, there is no limit on the substrate size.

The thickness of the sapphire substrates used for growth of nitride semiconductors can be from 0.05 mm to 5.0 mm. A substrate thickness of 0.1 mm is preferable in order to form a reformed domain pattern in a position that will not break the sapphire substrate itself. Better yet is a thickness of at least 0.3 mm when the diameter of the substrate is from 50 mm to 150 mm, and at least 0.5 mm when the substrate diameter exceeds 150 mm.

The growth surface of the nitride semiconductor is concave and the curvature of this concave surface can be from 0 km⁻¹ up to 160 km⁻¹.

In the case of reformed domain patterns formed inside sapphire substrates used for growth of nitride semiconductor layers, the plane shape of the pattern, as stated above is any of a striped shape, a lattice shape, a distribution of multiple polygons, a concentric circular shape, a spiral shape, or broken lines or dots that are symmetrical with respect to a vertical line through the center point of the sapphire substrate. To obtain an internally reformed sapphire substrate having a uniform warping shape and amount in the substrate surface, it is preferable to use a shape that is symmetrical with any of broken lines or dots with respect to a vertical line through the center point of the substrate or a lattice pattern.

A pitch between lines of 50 μm to 2000 μm is preferable, and 100 μm to 1000 μm is better yet; 200 μm to 500 μm is even better when mass production is taken into consideration.

The formation position of at least one type of reformed domain pattern is preferably set to at least 3% and no more than 95% of substrate thickness and better yet at least 3% and no more than 50%, measuring from the growth surface of the substrate. Multiple reformed domain patterns can be formed at formation positions that differ in the direction of the depth of the substrate.

It has been the practice when partitioning light-emitting elements having a nitride semiconductor layer stacked on a sapphire substrate to back-grind the sapphire substrate following formation of the nitride semiconductor layer to a thickness of about 100 μm, and then form a pattern for partitioning within the sapphire substrate, but a reformed domain pattern with the plane shape of a lattice established prior to formation of the nitride semiconductor layer can also be used for the final partitioning of LED chips. In this case it is preferable to form the pattern at a position such that the pattern will remain within the thickness that remains following the process of back-grinding to substrate.

FIG. 3 (a) through (d) shows the process of epitaxial growth of a nitride semiconductor layer on a sapphire substrate. Such methods as MOCVD, HVPE, and MBE can be used for layer formation. First the sapphire substrate undergoes thermal cleaning (FIG. 3 (a)), followed by growth of a low-temperature buffer layer 8 (FIG. 3 (b)). Next comes the growth of an n-GaN layer 9 (FIG. 3 (d)) and an InGaN active layer 10 with a multi quantum well structure (FIG. 3 (d)).

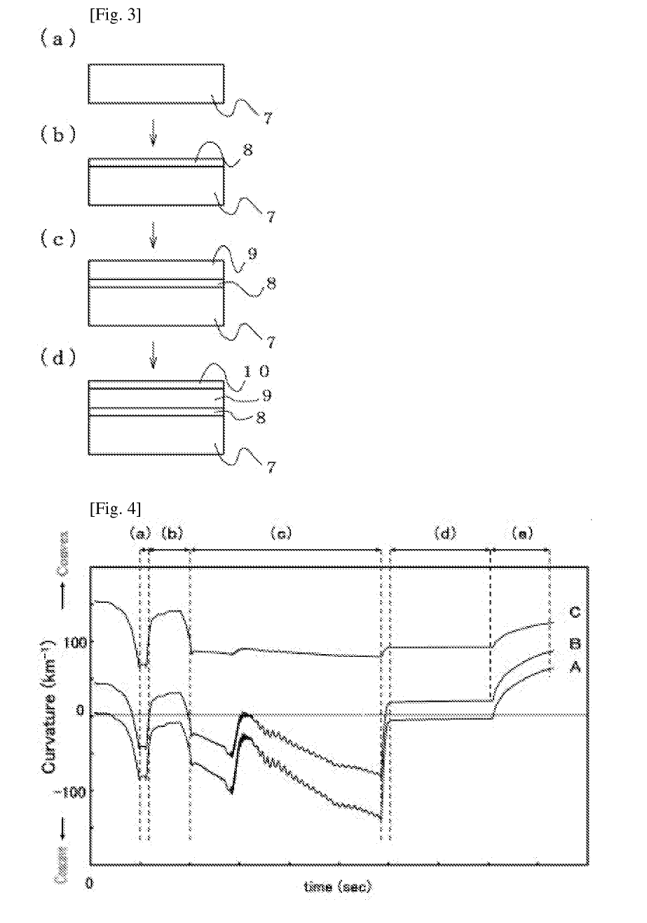

FIG. 4 shows an example of in-situ observation during the process of epitaxial growth of a nitride semiconductor layer. As described in Non-Patent Document 2, it is possible to perform quantitative analysis, through in-situ observation, of sapphire substrate behavior during layer growth. That is, it can be known how a substrate's warping shape and amount change during layer growth.

In FIG. 4 the horizontal axis shows time and the vertical axis shows curvature (km⁻¹) of the substrate growth surface. The positive direction of the vertical axis shows increasing convexity of the growth surface and the negative direction shows increasing concavity of the growth surface.

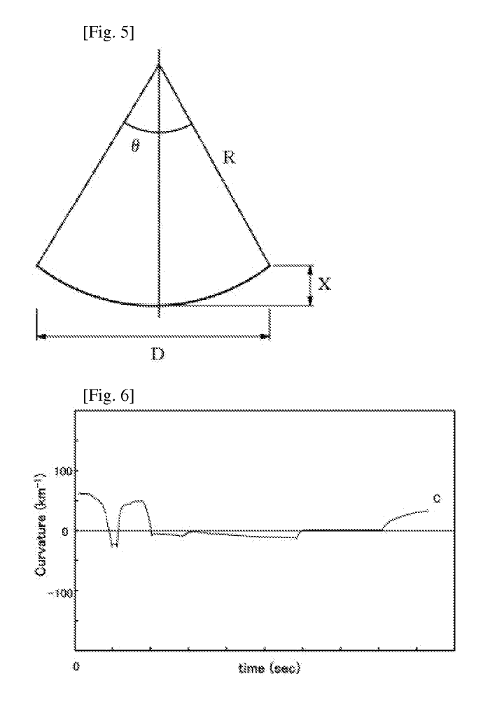

It is possible to calculate the amount of substrate warping from the curvature of the substrate. That is, as shown in FIG. 5, with R the substrate curvature radius as R, the amount of warping X (μm) of a substrate with curvature 1/R can be found using the substrate diameter as an approximation of D; simply put, when the diameter of the substrate is 50 mm, it is 0.322 times the curvature (km⁻¹) and when the diameter of the substrate is 150 mm, it is 1.250 times the curvature (km⁻¹).

Spectrum A in FIG. 4 shows an example using a conventional sapphire substrate without reformed domain formation.

In FIG. 4, (a) through (e) correspond to the course of each layer formation process. That is, (a) corresponds to thermal cleaning of the substrate, (b) to growth of a low-temperature buffer layer, (c) to growth of an n-GaN layer, (d) to growth of an InGaN active layer, and (e) to the cool-down process.

Spectrum A of FIG. 4 is used to explain the behavior of the substrate in FIG. 4 (a) through (e).

In the stage of transition to (a) thermal cleaning, the concavity of the substrate growth surface intensifies because of the temperature difference between the upper and lower surfaces of the sapphire substrate, and curvature changes greatly.

Next the temperature drops, normally to about 500 to 600° C., and in the stage of transition to (b) growth of the low-temperature buffer layer the concavity of the substrate weakens and curvature is slightly reduced.

Next the temperature rises to 1000° C. again and in the transition to (c) growth of the n-GaN layer the concavity of the substrate growth surface intensifies because of the difference between the lattice constants of the nitride semiconductor and the sapphire substrate, and curvature changes greatly. As layer growth progresses the curvature increases in proportion to the thickness of the layer, and so uniformity of layer thickness and layer quality on the surface of the substrate deteriorates markedly. It is said to be difficult technically to control uniformity of the substrate surface by means of layer growth conditions alone. Within the nitride semiconductor layer there is the problem, moreover, that dislocations occur to relieve stress and layer quality deteriorates.

Next the temperature drops to about 700 to 800° C. and in the transition to the stage of (d) InGaN active layer growth the uniformity the thickness of the InGaN active layer and of the In composition within the InGaN affect the uniformity of the light-emitting wavelength surface and thus affect the production yield of LED chips. Because the thickness of the InGaN active layer and the In composition are affected by the layer growth temperature, the ideal is to make the curvature of the substrate as close to 0 as possible during layer growth in order to improve the temperature uniformity on the surface of the substrate.

Finally in the substrate's (e) cool-down stage, the shape of the substrate is again warped greatly by the difference in indices of thermal expansion, and so the substrate's curvature at the end of the series of layer growth processes is great. This causes the problem that the process of back-grinding before cutting into LED chips is difficult.

As described above with reference to spectrum A, when the conventional sapphire substrate is used it is possible to make the substrate curvature nearly 0 in the InGaN active layer growth stage, but there is the shortcoming that the substrate's behavior is great during the layer growth processes and there is no way to avoid a large substrate curvature on completion of layer growth.

Next in-situ observation example No. 1, in which a nitride semiconductor layer is grown on the internally reformed sapphire substrate of this invention fabricated by forming a reformed domain pattern within a conventional sapphire substrate, is shown by spectrum B in FIG. 4.

For the initial state of the internally reformed sapphire substrate in spectrum B it is preferable to for a reformed domain pattern such that the substrate surface has a warp even more convex than the conventional sapphire substrate. It is possible by this means to reduce the substrate warping behavior relative to spectrum A, which used a conventional sapphire substrate.

As the initial convexity in spectrum B was greater than that in spectrum A, in spectrum C of FIG. 4 the pitch between lines and the pattern formation position were adjusted when forming a reformed domain pattern within a conventional sapphire substrate and the initial state of the sapphire substrate was warped with an even greater convexity than in spectrum B.

In spectrum C it is possible to further reduce substrate behavior through the layer formation processes. That is, it shows the effect of counteracting stresses generated during layer growth by stresses in the substrate that is even greater than shown in spectra A and B.

In comparison with the case of use of a conventional sapphire substrate, the nitride semiconductors from which spectra B and C above were obtained showed suppressed warping of the substrates during layer growth and reduced substrate warping behavior, and so layer quality and uniformity were improved.

At the same time, however, there is the problem that the initial state of the internally reformed sapphire substrates was a greatly warped convex surface, and as a result the substrate curvature in the InGaN active layer growth stage and at the completion of layer growth was greater than when a conventional sapphire substrate was used.

That is, it is preferable that the internally reformed sapphire substrate of this invention have, as shown in spectrum C in FIG. 6, reduced substrate warping behavior and at the same time reduced substrate curvature in the InGaN active layer growth stage and at the completion of layer growth.

It is possible by this means to improve the layer quality and uniformity of the nitride semiconductor layer and also to improve the light-emitting wavelength uniformity of nitride semiconductor photo-emitter elements.

It is desirable, therefore, that sapphire substrates prepared in advance to counteract the highly convex substrate curvature that would result from reformed domain pattern formation be used as the sapphire substrates prior to formation of the reformed domain patterns.

As stated previously, it is possible to use as the sapphire substrate for reformed pattern formation one that has a concave layer formation surface on the nitride semiconductor layer, the curvature of the concave surface being greater than 0 km⁻¹ and no more than 160 km⁻¹. And for the reasons stated previously, it is preferable that the layer growth surface of the nitride semiconductor layer be concave and that the curvature of this concave surface be between 40 km⁻¹ and 150 km⁻¹, and better yet between 85 km⁻¹ and 150 km⁻¹.

As described above, it is possible by using the internally reformed sapphire substrates of this invention to obtain nitride semiconductor layer growth bodies with improved nitride semiconductor layer quality and uniformity.

Using the nitride semiconductor layer growth bodies of this invention it is possible to constitute nitride semiconductor devices, including photo-emitter elements, electron devices, or photo-receptor elements, having improved quality and yield.

Further, it is possible by epitaxial growth on the nitride semiconductor layer growth bodies of this invention to form thick of nitride semiconductor layers to a thickness that can exist independently, then separate the nitride semiconductor layer growth bodies used as bed substrates to yield nitride semiconductor bulk substrates that comprise thick nitride semiconductor layers.

When a thick nitride semiconductor layer is formed on the internally reformed sapphire substrate of this invention it is possible to suppress substrate warping that occurs during or after the process of growth of the layer, and so it is possible to grow thick nitride semiconductor layers having a thickness to exist independently without causing cracking. By removing the thick nitride semiconductors layers thus obtained from the internally reformed sapphire substrates it is possible to provide bulk substrates of nitride semiconductor without the use of complicated processes. As nitride semiconductor bulk substrates t is possible to manufacture, in particular, nitride semiconductor bulk substrates that comprise AlₓIn_{y}Ga_{z}N (where x+y+z=1, x≧0, y≧0, and z≧0).

Next is a concrete explanation of embodiments of this invention. Reformed domain patterns were formed within sapphire substrates using the laser conditions shown in table 2, and the effect on substrate warping shape and amount of the substrate were examined. The results are shown in embodiments 1 and 2.

TABLE 2

| | |
|---|---|
| Wavelength (nm) | 1045 |
| Pulse Width (sec) | 500 × 10⁻¹⁵ |
| Pulse Repetition Rate (kHz) | 100 |
| Spot Size (μm) | 1.6 to 3.5 |
| Laser Power (W) | 0.3 |
| Stage Scan Speed (mm/s) | 400 |

### Embodiment 1

Two-inch sapphire substrates with one surface polished were used as the sapphire substrates for formation of reformed domain patterns. The substrate thickness was 430 μm. The shape and amount of substrate warping prior to formation of the reformed domain patterns was measured with a laser interferometer.

Next the sapphire substrates were mounted on the sample stage of a pulsed laser apparatus and reformed domain patterns were formed within the sapphire substrates.

Table 3 shows the pattern shapes, pitches between lines, formation positions reformed layer length, and machining time per substrate for samples 1 through 9. Following formation of the reformed domain patterns the substrate shape of the sapphire substrates was measured with a laser interferometer and the amount of warping and substrate thickness were measured with a linear gauge and a laser interferometer. “O.F.” in table refers to the orientation flat of the substrate.

TABLE 3

| | | | Formation | Reformed | Machining |
|---|---|---|---|---|---|
| Sample | Pattern | Pitch | position | Layer Length | Time |
| No. | Shape | (μm) | (μm) | (μm) | (min) |
| No. 1 | Stripe | 100 | 110 | 25 | 5 |
| No. 2 | (perpendicular | | 230 | 30 | 5 |
| No. 3 | to O.F.) | | 350 | 40 | 5 |
| No. 4 | Stripe | | 110 | 25 | 5 |
| No. 5 | (parallel | | 230 | 30 | 5 |
| No. 6 | to O.F.) | | 350 | 40 | 5 |
| No. 7 | Lattice | | 110 | 25 | 10 |
| No. 8 | | | 230 | 30 | 10 |
| No. 9 | | | 350 | 40 | 10 |

Table 4 shows shape and amount of substrate warping before and after formation of reformed domain patterns and the symmetry of warping shape of the substrate surfaces following pattern formation. The substrate warp shape shown is the shape of the growth surface.

TABLE 4

| | Before | | | | |
|---|---|---|---|---|---|
| Sample | Pattern Formation | | After Pattern Formation | | |
| No. | Shape | Warp (μm) | Shape | Warp (μm) | Symmetry |
| No. 1 | Concave | 3 | Convex | 40 | Change of |
| No. 2 | Concave | 4 | Concave | 4 | shape parallel |
| No. 3 | Concave | 5 | Concave | 20 | to O.F. |
| No. 4 | Concave | 4 | Convex | 40 | Change of shape |
| No. 5 | Concave | 3 | Concave | 3 | perpendicular |
| No. 6 | Concave | 5 | Concave | 20 | to O.F. |
| No. 7 | Concave | 2 | Convex | 40 | Concentric |
| No. 8 | Concave | 2 | Concave | 2 | change |
| No. 9 | Concave | 3 | Concave | 20 | |

### Embodiment 2

Four-inch sapphire substrates with one surface polished were used as the sapphire substrates for formation of reformed domain patterns. The substrate thickness was 650 μm. As with embodiment 1, the shape and amount of substrate warping prior to formation of the reformed domain patterns was measured with a laser interferometer.

Next the sapphire substrates were mounted on the sample stage of a pulsed laser apparatus and reformed domain patterns were formed within the sapphire substrates. Table 5 shows the pattern shapes, pitches, and formation positions for samples 10 through 19.

TABLE 5

| | | Pitch | Formation position |
|---|---|---|---|
| Sample No. | Pattern Shape | (μm) | (μm) |
| No. 10 | Lattice | 500 | 110 |
| No. 11 | | 500 | 110 |
| No. 12 | | 500 | 340 |
| No. 13 | | 500 | 340 |
| No. 14 | | 500 | 570 |
| No. 15 | | 500 | 570 |
| No. 16 | | 500 and 500 | 110 and 570 |
| No. 17 | | 500 and 500 | 110 and 570 |
| No. 18 | | 500 and 250 | 110 and 570 |
| No. 19 | | 430 | 110 |

Following formation of the reformed domain patterns the warping shape of the substrates was measured with a laser interferometer and the amount of warping and substrate thickness was measured with a linear gauge. Table 6 shows a comparison of the shape and amount of substrate warping before and after formation of reformed domain patterns and the curvature calculated from the amount of warping. The substrate warp shape shown is the shape of the growth surface.

TABLE 6

| | Before Pattern Formation | | | After Pattern Formation | | |
|---|---|---|---|---|---|---|
| | | Warp | Curvature | | Warp | Curvature |
| | Shape | (μm) | (km⁻¹) | Shape | (μm) | (km⁻¹) |
| No. 10 | Concave | 7 | 5.6 | Convex | 47 | 37.6 |
| No. 11 | Concave | 7 | 5.6 | Convex | 52 | 41.6 |
| No. 12 | Concave | 14 | 11.2 | Concave | 10 | 8 |
| No. 13 | Concave | 6 | 4.8 | Concave | 8 | 6.4 |
| No. 14 | Concave | 8 | 6.4 | Concave | 12 | 9.6 |
| No. 15 | Concave | 9 | 7.2 | Concave | 11 | 8.8 |
| No. 16 | Concave | 8 | 6.4 | Convex | 50 | 40 |
| No. 17 | Concave | 10 | 8 | Convex | 46 | 36.8 |
| No. 18 | Concave | 9 | 7.2 | Convex | 47 | 37.6 |
| No. 19 | Concave | 7 | 5.6 | Convex | 63 | 50.4 |

Table 7 shows the dependence on formation position and pitch between lines of the amount of change in substrate curvature following reformed domain pattern formation. [T.N.: This paragraph may be a hold-over from an earlier draft—the table is no longer present.]

### Embodiment 3

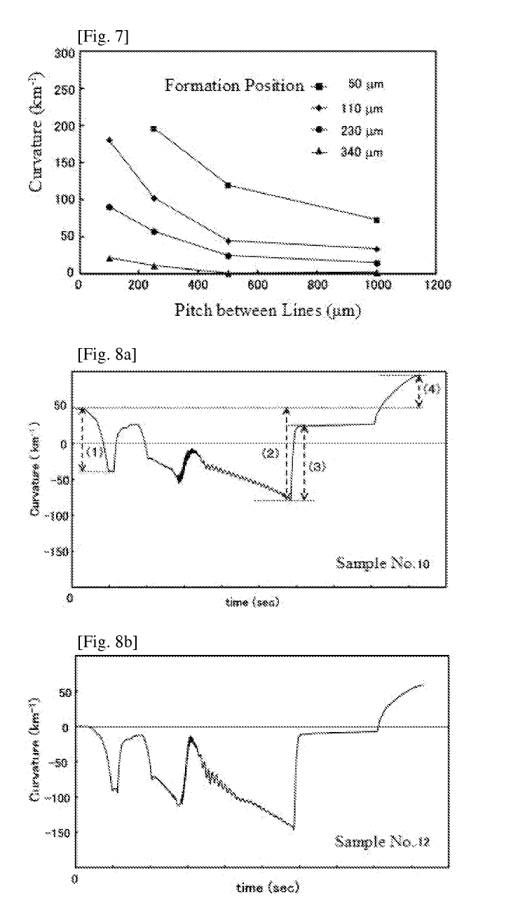

Of the sapphire substrates in which reformed domain patterns were formed in embodiment 2, samples 10, 12, 14, 16, and 18 and a conventional sapphire substrate in which no pattern had been formed (sample 20) were introduced simultaneously into an MOCVD apparatus and gallium nitride layers were grown on the sapphire substrates. FIG. 7 shows the layer growth temperature and layer thickness in each growth processes.

TABLE 7

| | Growth Temperature | Layer Thickness |
|---|---|---|
| | (° C.) | (nm) |
| AlGaN buffer layer | 550 | 500 |
| n-GaN layer | 1070 | 5000 |
| GaN/InGaN active layer | 750 | 100/2 |

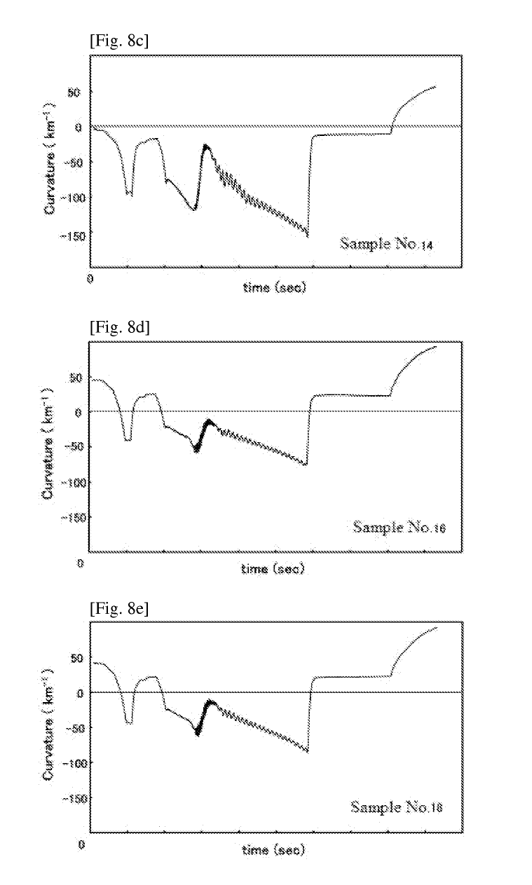

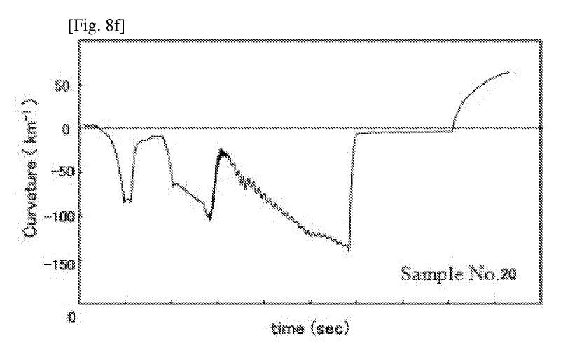

Results of in-situ observation of the samples are shown in FIG. 8a through FIG. 8f. Table 8 shows the substrate warping shape and amount and the curvature for each sample and table 9 shows the amount of curvature change in each stage.

In table 9, (1) through (4) indicate the change (1) at the time of thermal cleaning transition relative to the initial shape of the substrates, (2) at the time of n-GaN layer growth relative to the initial shape of the substrates, (3) at the time of GaN/InGaN layer growth transition relative to the completion of n-GaN growth, and (4) at completion of the cool-down relative to the initial shape of the substrates, as shown in FIG. 8.

TABLE 8

| | Substrate | Warp | Curvature |
|---|---|---|---|
| Sample No. | Shape | (μm) | (km⁻¹) |
| No. 10 | Convex | 47 | 37.6 |
| No. 12 | Concave | 10 | 8 |
| No. 14 | Concave | 12 | 9.6 |
| No. 16 | Convex | 50 | 40 |
| No. 18 | Convex | 47 | 36.8 |
| No. 20 | Concave | 2 | 1.6 |

TABLE 9

| | Curvature Change (km⁻¹) | | | |
|---|---|---|---|---|
| | (1) at time | (2) at time | (3) at time of | (4) at |
| | of thermal | of n-GaN | GaN/InGaN | completion |
| | cleaning | layer growth | layer growth | of cool down |
| | transition | relative | transition | relative to |
| | relative to | to initial | relative to | initial |
| Sample | initial shape | shape of | completion of | shape of |
| No. | of substrate | substrate | n-GaN growth | substrate |
| No. 10 | 88 | 126 | 101 | 44 |
| No. 12 | 89 | 142 | 131 | 58 |
| No. 14 | 90 | 144 | 134 | 59 |
| No. 16 | 86 | 121 | 101 | 50 |
| No. 18 | 85 | 119 | 97 | 48 |
| No. 20 | 85 | 138 | 129 | 60 |

(1) Judging from the amount of change in substrate curvature at the time of thermal cleaning transition relative to the initial shape of the substrates, no major difference in the amount of curvature change was found among samples 10, 12, 14, 16, and 18, which were sapphire substrates in which reformed domain patterns have been formed, and sample 20, a conventional sapphire substrate in which no pattern had been formed.

(2) Judging from the amount of change in substrate curvature at the time of n-GaN layer growth relative to the initial shape of the substrates, a greater effect in suppressing substrate curvature change at the time of n-GaN layer growth was found in samples 10, 16 and 18, which had patterns formed in positions there were shallow in distance from the surface of the sapphire substrate, than in the other samples.

(3) Judging from the amount of change in substrate curvature at the time of GaN/InGaN layer growth transition relative to the completion of n-GaN growth, a greater effect in suppressing substrate curvature change at the time of GaN/InGaN layer growth transition relative to the completion of n-GaN growth was found in samples 10, 16 and 18, which had patterns formed in positions there were shallow in distance from the surface of the sapphire substrate, than in the other samples.

(4) Judging from the amount of change in substrate curvature at completion of the cool-down relative to the initial shape of the substrates, a greater effect in suppressing substrate curvature change was found in samples 10, 16 and 18, which had patterns formed in positions there were shallow in distance from the surface of the sapphire substrate, than in the other samples.

Investigation was made of the gallium nitride layer thickness uniformity and crystal quality in samples 10, 12, 14, 16, 18, and 20 obtained from the processes above.

It was found that in comparison with sample 20 in which a reformed domain pattern had not been formed, sample 10 had better uniformity of layer thickness. It is thought that this is because the pattern formation position was shallow in distance from the surface of the sapphire substrate, and so n-GaN layer formation took place with the substrate shape in a flatter state.

The FWHM values of the gallium nitride (001) plane and (102) plane found by X-ray diffraction rocking curve measurement were 203 arcsec and 418 arcsec for sample 10 and 242 arcsec and 579 arcsec for sample 20 in which no reformed domain pattern had been formed. From that result it can be seen that sample 10 in which a reformed domain pattern had been formed had a gallium nitride layer with better crystal than sample 20 in which no reformed domain pattern had been formed.

It can be seen from the results above that when epitaxial growth of a nitride semiconductor layer is performed using the internally reformed sapphire substrate of this invention it is possible to suppress substrate warping and minimize substrate warping behavior, and so layer quality and uniformity is improved.

1. Among monocrystalline substrates used for formation of monocrystalline layers by means of epitaxial growth, an internally reformed substrate for epitaxial growth in which reformed domain patterns are formed within a monocrystalline substrate by means of multiphoton absorption using a pulsed laser.

2. Among monocrystalline substrates used for formation of monocrystalline layers by means of epitaxial growth, an internally reformed substrate for epitaxial growth in which reformed domain patterns are formed within a monocrystalline substrate by means of multiphoton absorption using a pulsed laser that is condensed and scanned through a polished surface of the monocrystalline substrate.

3. An internally reformed substrate for epitaxial growth as described in claim 1, wherein the material of the monocrystalline substrate is any of sapphire, nitride semiconductor, Si, GaAs, quartz crystal, or SiC.

4. A crystal growth layer body in which at least one crystal layer is formed on the growth surface of an internally reformed substrate for epitaxial growth as described in claim 1.

5. A device which has a crystal growth layer body as described in claim 4.

6. A bulk substrate that comprises a thick crystal growth layer as described in claim 4.

7. Among an internally formed sapphire substrate used for formation of a semiconductor layer formed by epitaxial growth, the internally reformed sapphire substrate for epitaxial growth of a semiconductor layer in which the reformed domain pattern is formed by means of multiphoton absorption using a pulsed laser.

8. Among an internally formed sapphire substrate used for formation of a semiconductor layer formed by epitaxial growth, the internally reformed sapphire substrate for epitaxial growth of a semiconductor layer in which the reformed domain pattern is formed within the sapphire substrate by means of multiphoton absorption using a pulsed laser condensed and scanned through a polished surface of the sapphire substrate.

9. A semiconductor layer growth body in which at least one semiconductor layer is formed on the growth surface of an internally reformed sapphire substrate for epitaxial growth of semiconductor layers as described in claim 7.

10. A semiconductor device which has a semiconductor growth layer body as described in claim 9.

11. A bulk semiconductor substrate that comprises a thick semiconductor layer as described in claim 9.

12. Among an internally formed sapphire substrate used for formation of a nitride semiconductor layer formed by epitaxial growth, the internally reformed sapphire substrate for epitaxial growth of a nitride semiconductor layer in which the reformed domain pattern is formed within the sapphire substrate by means of multiphoton absorption using a pulsed laser.

13. Among an internally formed sapphire substrate used for formation of a nitride semiconductor layer formed by epitaxial growth, the internally reformed sapphire substrate for epitaxial growth of a nitride semiconductor layer in which the reformed domain pattern is formed within the sapphire substrate by means of multiphoton absorption using a pulsed laser condensed and scanned through a polished surface of the sapphire substrate.

14. An internally reformed sapphire substrate for epitaxial growth of a nitride semiconductor as described in claim 12, wherein the plane shape of at least one type of reformed domain pattern is any of a striped shape, a lattice shape, a distribution of multiple polygons, a concentric circular shape, a spiral shape, or broken lines or dots that are symmetrical with respect to a vertical line through the center point of the sapphire substrate.

15. An internally reformed sapphire substrate for epitaxial growth of a nitride semiconductor layer as described in claim 14, wherein the position of formation of at least one type of reformed domain pattern is between 3% and 95% of the thickness of the substrate from the growth surface of the sapphire substrate and the pitch between lines making up the reformed domain pattern is at least 50 μm and no more than 2000 μm.

16. An internally reformed sapphire substrate for epitaxial growth of a nitride semiconductor as described in claim 12, wherein the plane shape of at least one type of reformed domain pattern the plane shape of at least one type of reformed domain pattern is any of broken lines or dots that are symmetrical with respect to a vertical line through the center point of the sapphire substrate or a lattice pattern and the reformed domain pattern is positioned between 3% and 50% of the thickness of the substrate from the growth surface of the sapphire substrate and the pitch between lines making up the reformed domain pattern is at least 50 μm and no more than 2000 μm.

17. A nitride semiconductor layer growth body in which at least one nitride semiconductor layer is formed on the growth surface of an internally reformed sapphire substrate for epitaxial growth of nitride semiconductor layers as described in claim 12.

18. A nitride semiconductor device which has a nitride semiconductor growth layer body as described in claim 17.

19. A nitride semiconductor device as described in claim 18 in which the nitride semiconductor device is any of a photo-emitter element, an electron device, or a photo-receptor element.

20. A bulk nitride semiconductor substrate that comprises a thick nitride semiconductor layer as described in claim 17.

21. A bulk nitride semiconductor substrate as described in claim 20 in which the bulk nitride semiconductor substrate comprises AlₓIn_{y}Ga_{z}N (where x+y+z=1, x≧0, y≧0, and z≧0).

22. Sapphire substrates used for formation of a semiconductor layer formed by epitaxial growth of claim 7, wherein a sapphire substrate for formation of reformed domains in which the shape of the sapphire substrate prior to formation of the reformed domain pattern has a semiconductor layer growth surface that is concave and the curvature of the concave surface is greater than 0 km⁻¹ and not greater than 160 km⁻¹.

23. Sapphire substrates used for formation of a semiconductor layer formed by epitaxial growth of claim 7, wherein a sapphire substrate for formation of reformed domains in which the shape of the sapphire substrate prior to formation of the reformed domain pattern has a semiconductor layer growth surface that is concave and the curvature of the concave surface is greater than 40 km⁻¹ and not greater than 150 km⁻¹.

24. Sapphire substrates used for formation of a semiconductor layer formed by epitaxial growth of claim 7, wherein a sapphire substrate for formation of reformed domains in which the shape of the sapphire substrate prior to formation of the reformed domain pattern has a semiconductor layer growth surface that is concave and the curvature of the concave surface is greater than 85 km⁻¹ and not greater than 150 km⁻¹.

25. A sapphire substrate for reformed domain formation as described in claim 22, wherein the diameter of the sapphire substrate prior to reformed domain formation is at least 50 mm and no more than 300 mm and its thickness is at least 0.05 mm and no more than 5.0 mm.

26. A method of manufacturing reformed domain substrates for epitaxial growth in which a reformed domain pattern is formed within a monocrystalline substrate used for formation of monocrystalline layers by epitaxial growth by means of multiphoton absorption using a pulsed laser that is condensed and scanned through a polished surface of the monocrystalline substrate and the warp shape and/or amount of warping of the monocrystalline substrate are controlled.

27. A method of manufacturing internally reformed substrates for epitaxial growth as described in claim 26 in which the material of the monocrystalline substrate is any of sapphire, nitride semiconductor, Si, GaAs, quartz crystal, or SiC.

28. A method of manufacturing crystal growth bodies in which at least one crystal layer is formed on the growth surface of an internally reformed substrate for epitaxial growth as described in claim 26.

29. A method of manufacturing devices that are fabricated using crystal growth bodies as described in claim 28.

30. A method of manufacturing bulk substrates that are fabricated using crystal growth body thick films as described in claim 28.

31. A method of manufacturing internally reformed sapphire substrates for semiconductor layer epitaxial growth in which a reformed domain pattern is formed within the sapphire substrate used for formation of semiconductor layers by epitaxial growth by means of multiphoton absorption using a pulsed laser that is condensed and scanned through a polished surface of the sapphire substrate and the warp shape and/or amount of warping of the sapphire substrate are controlled.

32. A method of manufacturing semiconductor layer growth bodies in which at least one semiconductor layer is formed on the growth surface of an internally reformed sapphire substrate for epitaxial growth of semiconductor layers as described in claim 31.

33. A method of manufacturing semiconductor devices in which fabrication is done using semiconductor layer growth bodies as described in claim 32.

34. A method of manufacturing semiconductor bulk substrates in which fabrication is done using thick layers of semiconductor layer growth bodies as described in claim 32.

35. A method of manufacturing internally reformed sapphire substrates for epitaxial growth of nitride semiconductor layers in which a reformed domain pattern is formed within the sapphire substrate used for formation of nitride semiconductor layers by epitaxial growth by means of multiphoton absorption using a pulsed laser that is condensed and scanned through a polished surface of the sapphire substrate and the warp shape and/or amount of warping of the sapphire substrate are controlled.

36. A method of manufacturing internally reformed sapphire substrates for epitaxial growth of nitride semiconductor layers as described in claim 35 in which the plane shape of at least one type of reformed domain pattern is any of a striped shape, a lattice shape, a distribution of multiple polygons, a concentric circular shape, a spiral shape, or broken lines or dots that are symmetrical with respect to a vertical line through the center point of the sapphire substrate.

37. An method of manufacturing internally reformed sapphire substrates for epitaxial growth of a nitride semiconductor layer as described in claim 36 in which the position of formation of at least one type of reformed domain pattern is between 3% and 95% of the thickness of the substrate from the growth surface of the sapphire substrate and the pitch between lines making up the reformed domain pattern is at least 50 μm and no more than 2000 μm.

38. An method of manufacturing internally reformed sapphire substrates for epitaxial growth of a nitride semiconductor layer as described in claim 36 in which the plane shape of at least one type of reformed domain pattern the plane shape of at least one type of reformed domain pattern is any of broken lines or dots that are symmetrical with respect to a vertical line through the center point of the sapphire substrate or a lattice pattern and the reformed domain pattern is positioned between 3% and 50% of the thickness of the substrate from the growth surface of the sapphire substrate and the pitch between lines making up the reformed domain pattern is at least 50 μm and no more than 2000 μm.

39. A method of manufacturing nitride semiconductor layer growth bodies in which at least one nitride semiconductor layer is formed on the growth surface of an internally reformed sapphire substrate for epitaxial growth of a nitride semiconductor layer as described in claim 35.

40. A method of manufacturing nitride semiconductor devices in which fabrication is done using nitride semiconductor layer growth bodies as described in claim 39.

41. A method of manufacturing nitride semiconductor devices as described in claim 40 in which the device is any of a photo-emitter element, an electron device, or a photo-receptor element.

42. A method of manufacturing nitride semiconductor bulk substrates in which fabrication is done using a nitride semiconductor layer growth body thick layer as described in claim 39.

43. Production method of a nitride semiconductor bulk substrate as described in claim 42 in which the nitride semiconductor bulk substrate comprises AlₓIn_{y}Ga_{z}N (where x+y+z=1, x≧0, y≧0, and z≧0).

44. The method of manufacturing internally reformed substrates for semiconductor layer epitaxial growth of claim 31, further comprising a method of manufacturing internally reformed sapphire substrates for epitaxial growth of semiconductor layers in which the shape of the sapphire substrate prior to formation of the reformed domain pattern has a semiconductor layer growth surface that is concave and the curvature of the concave surface is greater than 0 km⁻¹ and not greater than 160 km⁻¹.

45. The method of manufacturing internally reformed substrates for semiconductor layer epitaxial growth of claim 31, further comprising a method of manufacturing internally reformed sapphire substrates for epitaxial growth of semiconductor layers in which the shape of the sapphire substrate prior to formation of the reformed domain pattern has a semiconductor layer growth surface that is concave and the curvature of the concave surface is greater than 40 km⁻¹ and not greater than 150 km⁻¹.

46. The method of manufacturing internally reformed substrates for semiconductor layer epitaxial growth of claim 31, further comprising a method of manufacturing internally reformed sapphire substrates for epitaxial growth of semiconductor layers in which the shape of the sapphire substrate prior to formation of the reformed domain pattern has a semiconductor layer growth surface that is concave and the curvature of the concave surface is greater than 85 km⁻¹ and not greater than 150 km⁻¹.

47. The method of manufacturing internally reformed substrates for semiconductor layer epitaxial growth of claim 44, further comprising a method of manufacturing internally reformed sapphire substrates for epitaxial growth of semiconductor layers in which the diameter of the sapphire substrate prior to reformed domain formation is at least 50 mm and no more than 300 mm and its thickness is at least 0.05 mm and no more than 5.0 mm.
